(19) United States
(12) Patent Application Publication
(10) Pub. No.: US 2015/0348802 A1
(43) Pub. Date: Dec. 3, 2015

(54) THINNED FLAT PLATE HEAT PIPE FABRICATED BY EXTRUSION

(71) Applicant: ELECTRONICS AND TELECOMMUNICATIONS RESEARCH INSTITUTE, Daejeon (KR)

(72) Inventor: Seok Hwan MOON, Daejeon (KR)

(73) Assignee: ELECTRONICS AND TELECOMMUNICATIONS RESEARCH INSTITUTE, Daejeon (KR)

(21) Appl. No.: 14/825,412

(22) Filed: Aug. 13, 2015

Related U.S. Application Data
(62) Division of application No. 13/287,193, filed on Nov. 2, 2011.

(30) Foreign Application Priority Data
Dec. 13, 2010 (KR) 10-2010-0126778

(51) Int. Cl. H01L 21/48; B21C 23/00

(52) U.S. Cl. CPC H01L 21/4878; B21C 23/00

(57) ABSTRACT

A method for fabricating a thinned flat plate heat pipe, including forming a body part having a flat plate shape by using an extrusion process, forming a through-hole in the longitudinal direction of the body part, and forming one or more grooves on at least one side of an inner wall of the through-hole to allow a working fluid to flow.

### CROSS-REFERENCE TO RELATED APPLICATIONS

This application is a divisional application of co-pending U.S. application Ser. No. 13/287,193, filed Nov. 2, 2011, which claims priority under 35 U.S.C. §119 to Korea Patent Application No. 10-2010-0126778, filed Dec. 13, 2010. The disclosures of these U.S. and Korean applications are incorporated herein by reference.

### TECHNICAL FIELD

The present disclosure relates to a thinned flat plate heat pipe fabricated by extrusion. More particularly, the present disclosure relates to a thinned flat plate heat pipe that has a thin flat shape in which a predetermined through-hole is formed therein and includes a plurality of grooves having one or more edges formed on the inner surface of the through-hole to allow a liquid working fluid to flow by capillary force generated from the edge so as to further improve heat-transfer performance. Further, in the present disclosure, in a thinned flat plate heat pipe structure, the plurality of grooves are not formed throughout the inner surface of the through-hole but on only a part of one side or both side surfaces of the through-hole in order to ensure a steam flowing space which is a very important factor in the heat-transfer performance.

The present disclosure relates to a thinned flat plate heat pipe which can be variously applied to electronic equipment having a small-sized and thin-film structure and the thinned flat plate heat pipe structure according to the exemplary embodiment of the present disclosure can be fabricated through a simple extrusion process, thereby further improving productivity.

### BACKGROUND

Chips and systems packaged in electronic equipment have gradually been high-integrated and miniaturized with the development of a semiconductor manufacturing technology. Following this trend, since heat emission density of components included in the electronic equipments is significantly increased, a cooling mechanism for effectively dissipating the emitted heat is required. In particular, since the electronic equipments are thinned together with miniaturization, an adopted cooling device also needs to be small-sized and thinned.

As an example of the cooling device in the related art which can be adopted in the miniaturized electronic equipment, a heat sink, a fan, and a small-sized heat pipe having a circular cross section having a diameter of 3 mm or more may be used.

First, since the heat sink can be fabricated with flexible sizes and thicknesses, the heat sink has been widely used as a basic form of a cooling means in the meantime. However, when a significant micro size is required, a heat dissipation rate is relatively low with a decrease in a heat-transfer area.

Second, the fan is limited in fabricating the fan with the micro size and reliability is relatively low.

Third, the small-sized heat pipe having the circular structure cross section with the diameter of 3 mm or more may be crimped and used to be suitable for the thin film structure. However, since the small-sized heat pipe having the circular structure cross section has a cross section which is initially designed in a circular shape, when the small-sized heat pipe is crimped to be suitable for electronic equipment having the small-sized and thin-film structure, the heat-transfer performance is significantly reduced due to a structural change of a wick.

Accordingly, a thin-film type minute heat pipe of approximately 1 mm or less suitable for the electronic equipment having the small-sized and thin-film structure has been required to be developed.

### SUMMARY

The present disclosure has been made in an effort to provide a thinned flat plate heat pipe that has a thin flat shape in which a predetermined through-hole is formed therein and includes a plurality of grooves having one or more edges formed on the inner surface of the through-hole to allow a liquid working fluid to flow by capillary force generated from the edge so as to further improve heat-transfer performance.

Further, the present disclosure has been made in an effort to provide a thinned flat plate heat pipe in which the plurality of grooves are not formed throughout the inner surface of the through-hole but on only a part of one side or both side surfaces of the through-hole in order to ensure a steam flowing space which is a very important factor in the heat-transfer performance of a thinned flat plate heat pipe structure, such that the thinned flat plate heat pipe structure is fabricated through a simple extrusion process to thereby further improve productivity and be variously applied to electronic equipment having small-sized and thin-film structure.

An exemplary embodiment of the present disclosure provides a thinned flat plate heat pipe including: a body part having a flat plate shape; a through-hole formed in the longitudinal direction of the body part; and one or more grooves formed on at least one side of the inner wall of the through-hole and allowing a working fluid to flow.

Another exemplary embodiment of the present disclosure provides a method for fabricating a thinned flat plate heat pipe, including: forming a body part having a flat plate shape by using an extrusion process; forming a through-hole in the longitudinal direction of the body part; and forming one or more grooves allowing a working fluid to flow on at least one side of an inner wall of the through-hole.

According to exemplary embodiments of the present disclosure, a thinned flat plate heat pipe that has a thin flat shape in which a predetermined through-hole is formed therein and includes a small number of grooves having one or more edges formed on the inner surface of the through-hole to allow a liquid working fluid to flow by capillary force generated from the edge, such that the excellent capillary force can be acquired through structural transformation of the heat pipe itself without an additional wick for allowing the liquid working fluid therein to flow and heat-transfer performance can be further improved. And the thinned flat plate heat pipe is fabricated in a simple process to further improve productivity and be variously applied to small-sized and thin-film structure electronic equipments.

Further, according to exemplary embodiments of the present disclosure, a plurality of separation membranes are formed in one thinned flat plate heat pipe, such that a plurality of passages can be formed using one thinned flat plate heat pipe.

In addition, according to exemplary embodiments of the present disclosure, the grooves are not formed throughout the inner surface of the through-hole but a small number of grooves are formed on only one side or both side surfaces of the through-hole, such that a relatively large steam flowing passage space can be ensured on the inner wall of the through-hole on which the groove is not formed and an interface friction flowing resistance between gas and liquid can be fundamentally removed to achieve high heat-transfer performance. As described above, the grooves are formed on only a part of the inner wall of the through-hole to implement the thinned flat plate heat pipe having a small thickness.

Moreover, in the exemplary embodiments of the present disclosure, the grooves are formed on only a part of the inner wall of the through-hole to implement the thinned flat plate heat pipe having the small thickness, but the capillary force required for liquid flowing may be difficult to generate due to the small number of grooves. Therefore, a very thin wire bundle is inserted into the small number of grooves formed at one side or both sides of the through-hole to generate significant capillary force.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1A and 1B are a perspective view and a cross-sectional view for describing a thinned flat plate heat pipe according to a first exemplary embodiment of the present disclosure.

FIGS. 2A and 2B are cross-sectional views for describing a thinned flat plate heat pipe according to a second exemplary embodiment of the present disclosure.

FIG. 3 is a cross-sectional view for describing a thinned flat plate heat pipe according to a third exemplary embodiment of the present disclosure.

FIGS. 4A and 4B are cross-sectional views for describing a thinned flat plate heat pipe according to a fourth exemplary embodiment of the present disclosure.

FIG. 5 is a cross-sectional view for describing a thinned flat plate heat pipe according to a fifth exemplary embodiment of the present disclosure.

FIGS. 6A and 6B are a cross-sectional view for describing a thinned flat plate heat pipe according to a sixth exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to the accompanying drawings.

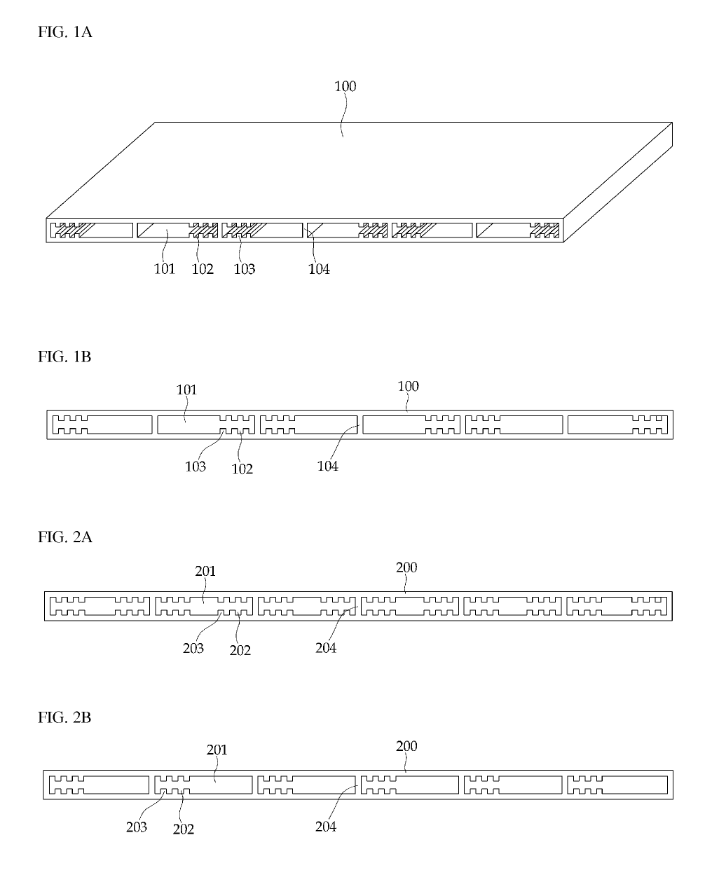

FIGS. 1A and 1B are a perspective view and a cross-sectional view for describing a thinned flat plate heat pipe according to a first exemplary embodiment of the present disclosure.

Referring to FIG. 1A, the thinned flat plate heat pipe has a thinned flat plate-shaped body part 100. Flat plate-shaped body part 100 may be constituted by a pipe-type metallic plate fabricated using an extrusion process.

Referring to FIG. 1B, a through-hole 101 having an empty space of a predetermined shape to transport a working fluid injected from the outside is formed in body part 100.

Referring to FIGS. 1A and 1B, a plurality of ‘ [symbol] ’-shaped grooves 102 extended in the same longitudinal direction as through-hole 101 are formed on the inner surface of through-hole 101. Grooves 102 may be formed by concave spaces generated among a plurality of convex portions 103 formed on the inner surface of the through-hole 101. Capillary force is generated by edges of a lower portion of ‘ [symbol] ’-shaped groove 102, such that a liquid working fluid flows.

Referring to FIGS. 1A and 1B, grooves 102 are not formed throughout the inner surface of each through-hole 101 but only one side surface of through-hole 101. For example, grooves 101 may be formed on only a left side surface of the first through-hole and the grooves 102 may be formed on only a right side surface of the second through-hole.

An appropriate number of separation membranes 104 may be formed in through-hole 104 in order to form a plurality of passages.

As described above, in the thinned flat plate heat pipe according to the first exemplary embodiment of the present disclosure, the liquid working fluid flows by the capillary force generated from the edges of plural ‘ [symbol] ’-shaped grooves 102 formed in through-hole 101, instead of a wick in the related art serving as a passage for allowing the liquid working fluid to flow (return) from a condenser section to an evaporator section. That is, an edge part of each ‘ [symbol] ’-shaped groove 102 may serve as the wick in the related art.

The edge part of groove 102 may have a polygonal structure having edges to allow the working fluid to flow and may have various shapes such as a triangular shape, a rectangular shape, a trapezoidal shape, a hemispherical shape, and a parabolic shape.

In the thinned flat plate heat pipe according to the first exemplary embodiment of the present disclosure configured as above, internal heat is emitted to the outside caused by the phase changes between gas and liquid caused by the injected liquid working fluid while a vacuum state is maintained in the heat pipe.

FIGS. 2A and 2B are cross-sectional views for describing a thinned flat plate heat pipe according to a second exemplary embodiment of the present disclosure.

Referring to FIGS. 2A and 2B, the thinned flat plate heat pipe according to the second exemplary embodiment of the present disclosure is constituted by a thinned flat plate shaped body part 200 similarly as in the first exemplary embodiment of the present disclosure.

A through-hole 201 having an empty space of a predetermined shape to transport the working fluid injected from the outside is formed in body part 200 and a plurality of ‘ [symbol] ’-shaped grooves 202 extended in the same longitudinal direction as through-hole 201 are formed on the inner surface of through-hole 201. ‘ [symbol] ’-shaped groove 202 is formed by a plurality of convex portions 203 formed on the inner surface of through-hole 201.

The capillary force is generated by edges of a lower portion of ‘ [symbol] ’-shaped groove 202, such that the liquid working fluid flows.

An appropriate number of separation membranes 204 may be formed in through-hole 201 in order to form a plurality of passages.

In the thinned flat plate heat pipe shown in FIG. 2A, plural grooves 202 extended in the longitudinal direction are formed on the inner surface of through-hole 201, however, grooves 202 are not formed throughout the inner surface of through-hole 201, but are formed on both side surfaces of through-hole 201. As illustrated in FIG. 2A, a plurality of convex portions 203 are formed on an inner surface of each of the plurality of passages, to thereby form a main passage and a plurality of grooves 202 on both a top inner wall and a bottom inner wall of the passage. In each passage, both the main passage and the grooves 202 extend along the longitudinal direction; a width of the main passage is larger than that of each of the grooves 202; and the grooves 202 are formed on both sides of the main passage. On the top inner wall, the main passage and the plurality of grooves 202 are formed at first locations thereof. On the bottom inner wall, the main passage and the plurality of grooves 202 are formed at second locations thereof. The first locations are symmetrical to the second locations with respect to a plane parallel to the top and bottom inner walls.

In the thinned flat plate heat pipe shown in FIG. 2B, plural grooves 202 extended in the longitudinal direction are formed on the inner surface of through-hole 201, however, grooves 202 are not formed throughout the inner surface of through-hole 201 but only one side surface of through-hole 201 and grooves 202 are formed in the same direction for each through-hole 201. For example, as shown in FIG. 2B, groove 202 may be formed on only a left surface of through-hole 201.

Meanwhile, since the thinned flat plate heat pipe according to the second exemplary embodiment of the present disclosure has the same operations and effects as the first exemplary embodiment of the present disclosure, a detailed description thereof may refer to the first exemplary embodiment of the present disclosure.

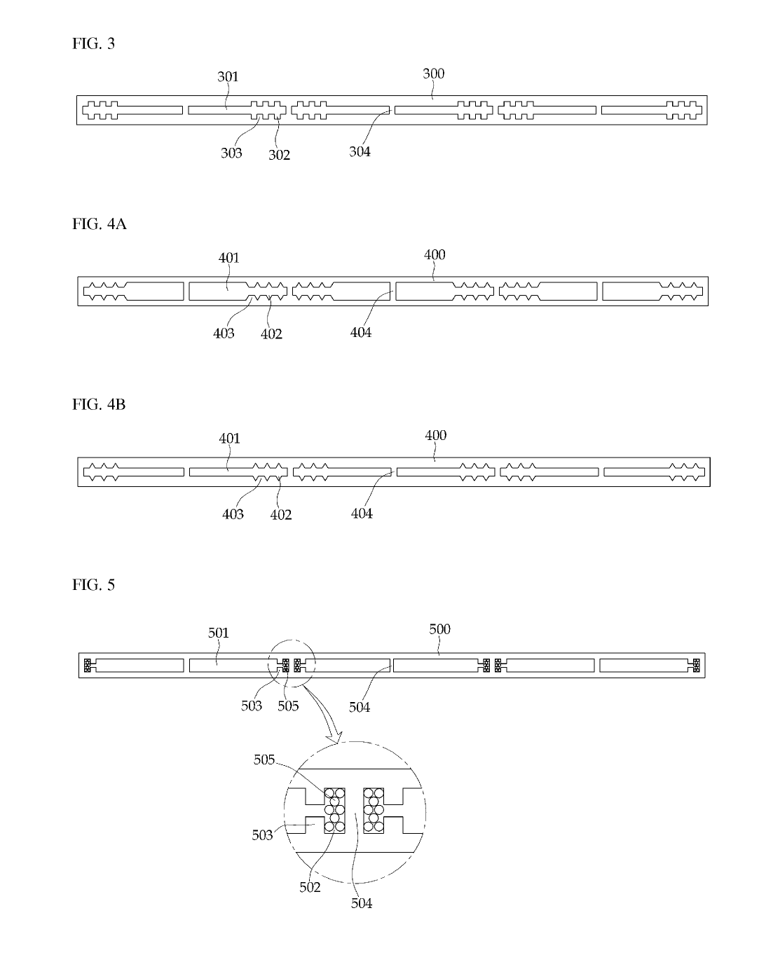

FIG. 3 is a cross-sectional view for describing a thinned flat plate heat pipe according to a third exemplary embodiment of the present disclosure.

Referring to FIG. 3, the thinned flat plate heat pipe according to the third exemplary embodiment of the present disclosure is constituted by a thinned flat plate shaped body part 300 similarly as in the first and second exemplary embodiments of the present disclosure.

The thinned flat plate heat pipe according to the third exemplary embodiment of the present disclosure basically has the same structure and function as the first and second exemplary embodiments. However, grooves 302 are formed as intaglio on the wall surface of a through-hole 301. Therefore, the capillary force is generated by edges formed in a lower portion of groove 302 formed as intaglio between portions not dug as intaglio on the wall surface of the through-hole 301, such that the liquid working fluid flows.

In the first and second exemplary embodiments, as grooves 102 and 202 are formed by convex portions 103 and 203 fabricated as embossment, the thicknesses of the walls of the through-holes 101 and 201 are relatively thin to significantly ensure a steam flowing space, while in the third exemplary embodiment, as groove 302 is fabricated as intaglio, the thickness of the wall of through-hole 301 is relatively thick to make the structure of the thinned flat plate heat pipe strong.

In the meantime, since the thinned flat plate heat pipe according to the third exemplary embodiment of the present disclosure has the same operations and effects as the first and second exemplary embodiments of the present disclosure, a detailed description thereof can refer to the first and second exemplary embodiments of the present disclosure.

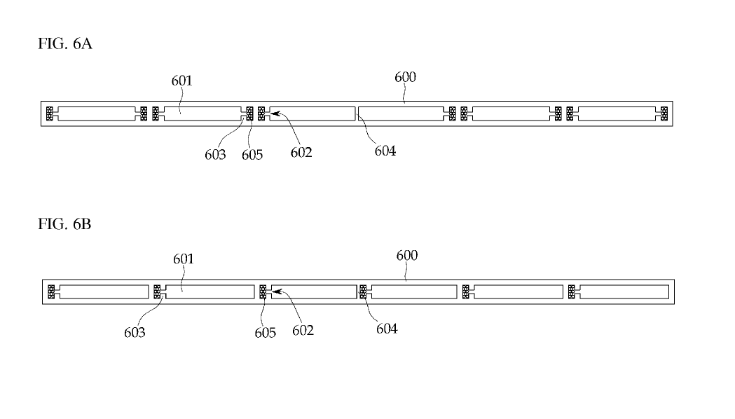

FIGS. 4A and 4B are cross-sectional views for describing a thinned flat plate heat pipe according to a fourth exemplary embodiment of the present disclosure.

Referring to FIGS. 4A and 4B, the thinned flat plate heat pipe according to the fourth exemplary embodiment of the present disclosure is constituted by a thinned flat plate-shaped body part 400 similarly as in the first, second, and third exemplary embodiments of the present disclosure.

The thinned flat plate heat pipe according to the fourth exemplary embodiment of the present disclosure basically has the same structure and function as the first, second, and third exemplary embodiments. However, grooves 402 in a through-hole 401 have cross sections which have not a quadrangular shape but a ‘V’ shape. Besides, the grooves formed in through-hole 401 may have various shapes such as the triangular shape, a spire shape, the rectangular shape, the trapezoidal shape, the hemispherical shape, and the parabolic shape.

In the thinned flat plate heat pipe shown in FIG. 4A, a trapezoidal convex portion 403 is formed in through-hole 401 as intaglio, such that ‘V’-shaped groove 402 is formed between convex portions 403. Meanwhile, in the thinned flat plate heat pipe shown in FIG. 4B, ‘V’-shaped groove 402 is formed in through-hole 401 as intaglio.

An appropriate number of separation membranes 404 may be formed in through-hole 401 in order to form a plurality of passages.

Meanwhile, since the thinned flat plate heat pipe according to the fourth exemplary embodiment of the present disclosure has the same operations and effects as the first, second, and third exemplary embodiments of the present disclosure, a detailed description thereof can refer to the first, second, and third exemplary embodiments of the present disclosure.

FIG. 5 is a cross-sectional view and a partially enlarged diagram for describing a thinned flat plate heat pipe according to a fifth exemplary embodiment of the present disclosure.

Referring to FIG. 5, the thinned flat plate heat pipe according to the fifth exemplary embodiment of the present disclosure is constituted by a thinned flat plate-shaped body part 500.

The flat plate-shaped body part 500 may be configured as a pipe-type metallic plate fabricated using the extrusion process. Further, a through-hole 501 having an empty space of a predetermined shape is formed in body part 500 to transport the working fluid injected from the outside.

A small number of ‘ [symbol] ’-shaped grooves 502 extended in the same longitudinal direction as through-hole 501 are formed on the inner surface of through-hole 501. Further, an appropriate number of separation membranes 504 may be formed in through-hole 504 in order to form a plurality of passages. Groove 502 is formed by a space between convex portion 503 and separation membrane 504 formed on the inner surface of through-hole 501.

Referring to FIG. 5, small number of grooves 502 extended in the longitudinal direction are formed on the inner surface of through-hole 501, however, grooves 5 are not formed throughout the inner surface of through-hole 501 but only one side surface of through-hole 501. For example, as shown in FIG. 5, each one ‘ [symbol] ’-shaped groove 502 may be formed by one convex portion 503 formed on one side surface of each through-hole 501.

Several stands of wires 505 are inserted into ‘ [symbol] ’-shaped groove 502 and the capillary force is generated through a gap formed between wires 505, such that the liquid working fluid can flow more effectively. Several strands of wires 505 may have a circular bundle shape.

As described above, in the thinned flat plate heat pipe according to the fifth exemplary embodiment of the present disclosure, the liquid working fluid flows by the capillary force generated by the gap of the strand of wires 505 installed inside ‘ [symbol] ’-shaped groove 502 in each through-hole, instead of the wick in the related art serving as the passage for allowing the liquid working fluid to flow (return) from the condenser section to the evaporator section.

In the thinned flat plate heat pipe according to the fifth exemplary embodiment of the present disclosure configured as above, the internal heat is emitted to the outside caused by the phase changes between gas and liquid caused by the injected liquid working fluid while the vacuum state is maintained in the heat pipe.

FIGS. 6A and 6B are a cross-sectional view for describing a thinned flat plate heat pipe according to a sixth exemplary embodiment of the present disclosure.

Referring to FIGS. 6A and 6B, the thinned flat plate heat pipe according to the sixth exemplary embodiment of the present disclosure is constituted by a thinned flat plate-shaped body part 600 similarly as in the fifth exemplary embodiment of the present disclosure.

A through-hole 601 having an empty space of a predetermined shape is formed in body part 600 to transport the working fluid injected from the outside and an appropriate number of separation membranes 604 may be formed in through-hole 601 in order to form a plurality of passages.

A small number of ‘ [symbol] ’-shaped grooves 602 extended in the same longitudinal direction as through-hole 601 are formed on the inner surface of through-hole 601. Groove 602 is formed by a space between convex portion 603 and separation membrane 604 formed on the inner surface of through-hole 601.

The liquid working fluid flows by the capillary force generated from a gap between the strand of wires 605 installed inside ‘ [symbol] ’-shaped grooves 602.

Referring to FIG. 6A, small number of grooves 602 extended in the longitudinal direction are formed on the inner surface of through-hole 601, however, grooves 602 are not formed throughout the inner surface of through-hole 601 but both side surfaces of through-hole 601.

Referring to FIG. 6B, small number of grooves 602 extended in the longitudinal direction are formed on the inner surface of through-hole 601, however, grooves 602 are not formed throughout the inner surface of through-hole 601 but one side surface of through-hole 601 in a predetermined direction.

Meanwhile, since the flat plate heat pipe according to the sixth exemplary embodiment of the present disclosure has the same operations and effects as the fifth exemplary embodiment of the present disclosure, a detailed description thereof can refer to the fifth exemplary embodiment of the present disclosure.

As described above, since the thinned flat plate heat pipes according to the first to sixth exemplary embodiment of the present disclosure have minute and excellent heat dissipation and heat-transfer performance with the thickness of approximately 2 mm or less, the thinned flat plate heat pipes may be effectively used as cooling means of electronic apparatuses having small-sized and thin-film structure.

Although the flat plate heat pipe according to the exemplary embodiments of the present disclosure has been described, various modifications can be made within the scopes of the appended claims, the detailed description of the present disclosure, and the accompanying drawings are also included in the present disclosure.

For example, grooves 102 to 602 according to the first to sixth exemplary embodiments of the present disclosure have the ‘ [symbol] ’ and ‘V’ shapes, but are not limited thereto and can be modified to various shapes to have one or more edge parts in grooves 102 to 602.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for fabricating a thinned flat plate heat pipe, comprising:
forming a body part having a flat plate shape by using an extrusion process;
forming a through-hole in the longitudinal direction of the body part; and
forming one or more grooves on at least one side of an inner wall of the through-hole to allow a working fluid to flow.

2. The method of claim 1, further comprising forming one or more separation membranes for separating the through-hole into a plurality of through-holes.

3. The method of claim 1, further comprising forming a bundle of wires in the groove.

4. The method of claim 1, wherein the forming of the one or more grooves includes forming one or more convex portions on the inner wall of the through-hole.

5. The method of claim 4, further comprising forming one or more separation membranes for separating the through-hole into a plurality of through-holes, wherein
each groove is a concave space formed between one of the convex portions and one of the separation membranes.
